(19) United States
(12) Patent Application Publication
(10) Pub. No.: US 2005/0258551 A1
(43) Pub. Date: Nov. 24, 2005

(54) Fine-pitch packaging substrate and a method of forming the same

(75) Inventors: Kwun-Yao Ho, Hsin Tien City (TW); Moriss Kung, Hsin Tien City (TW)

Correspondence Address: BRUCE H. TROXELL;SUITE 1404, 5205 LEESBURG PIKE, FALLS CHURCH, VA, 22041, US

(73) Assignee: Via Technologies, Inc.

(21) Appl. No.: 11/041,958

(22) Filed: Jan. 26, 2005

(30) Foreign Application Priority Data
May 21, 2004 (TW) 93114384

(51) Int. Cl. H01L 23/48; H01L 21/44

(52) U.S. Cl. 257/786; 257/784; 438/612

(57) ABSTRACT

A packaging substrate used in a fine-pitch packaging comprises a circuit board, a plurality of packaging pads, an isolation pattern, and a conductive plating layer. The bonding pads are formed on an upper surface of the circuit board for electrically connecting to respective die pads. The isolation pattern filling the space between the neighboring bonding pads can cover all the exposed surfaces of the circuit board. A portion of the isolation pattern adjacent to the bonding pads has a same or a smaller thickness with respect to the bonding pads, and an upper surface and a portion of the sidewall of the packaging pads are thus exposed. The conductive plating layer covering the upper surface and the exposed sidewall of the packaging pads can extend outward from the sidewall to result an increased connectable area.

### BACKGROUND OF THE INVENTION

(1) Field of the Invention

This invention relates to a fine-pitch packaging substrate and a method of forming the same, and more particularly to a packaging substrate with a high-density pad array and a method of forming the same.

(2) Description of Related Art

As the prosperity of the semiconductor fabrication technology, a central processing unit (CPU) characterized in small-size, multi-function, and high-speed becomes popular. Such a CPU needs an increased number of input/output (I/O) contacts to transmit data and signals for various functional demands. Thus, the density of I/O contacts must be increased to prevent an increasing packaging size. However, the density of I/O contacts formed on the packaging substrate is limited by the poor cleanness in packaging process; i.e., the packaging substrate must be lay with a bigger line width with respect to the line width on the die, and so the density of I/O contacts on the packaging substrate is limited thereby.

FIGS. 1 A and 1 B depict a schematic top view and a cross-section view of a packaging substrate utilized for a traditional wire-bonding (W/B) packaging. As shown, a circuit board 120 is provided as a main portion of the packaging substrate. A plurality of bonding pads 140 related to the die pads (not shown) is formed on an upper surface of the circuit board 120. A plurality of traces 150 is also formed on the circuit board 120 and connects to the respective bonding pads 140 for signal transmission.

An isolation layer 160 is formed on an upper surface of the circuit board 120 and fills the space between neighboring bonding pads 140 to prevent ion migration from shortening the circuit on the circuit board 120. A solder mask (SM) layer 180 is formed on the isolation layer 160 and covers part of an upper surface 140a of the bonding pads 140. Therefore, the opening 182 in the solder mask 180 has a smaller area with respect to the upper surface 140a of the bonding pad 140.

Basically, when a die is placed on the packaging substrate, an aligning error in between is unpreventable. Therefore, the openings 182 of the solder mask 180 must have some excessive area for tolerating the aligning error. It is also understood that the difference in sizes of the bonding pad 140 and the opening 182, as well as the aligning error, should be compensated during the manufacturing.

In addition, as shown in FIG. 1B, a pitch length P between the neighboring bonding pads 140 equals to a sum of a distance D1 between opposing sides 140b, 140c of the neighboring bonding pads 140 and the width D2 of the bonding pads 140. The distance D1 utilized as a buffer length to prevent ion migration from resulting short circuit is restricted by some process related parameters such as environmental cleanness and materials involved, and thus cannot be freely reduced. The width D2 of the bonding pads 140 should be larger than the width D3 of the opening 182. The width D3 of the opening 182 should be used to preserve some additional length for making sure that the die pads is successively connecting to the bonding pads 140 in the openings 182.

As mentioned, an increasing of I/O contact density on a traditional packaging substrate is limited by the fabrication process engaged and the materials involved. The effort to increase the density of I/O contacts with the same packaging process is definitely worthy and has become an important topic in developing the next generation IC design.

### SUMMARY OF THE INVENTION

The present invention provides a fine-pitch packaging substrate with bonding pads of reduced size to achieve a high pad density for the need of an increase of relative contacts on the die.

A fine-pitch packaging substrate of the present invention comprises a circuit board, a plurality of bonding pads, an isolation pattern, and a conductive plating layer. The bonding pads are formed on the circuit board for electrically connecting to the die pads. The isolation pattern is formed on the circuit board to fill the space between neighboring bonding pads and cover all the exposed surfaces of the circuit board. A portion of the isolation pattern adjacent to the bonding pads has a same or smaller thickness with respect to the bonding pads, and an upper surface and a portion of the sidewall of the bonding pads is therefore exposed. The conductive plating layer covers both the upper surface and the exposed sidewall of the bonding pads, and extends outward from the sidewall to expand the connectable area on the fine-pitch packaging substrate.

This invention also discloses a fabrication method of the fine-pitch packaging substrate. Firstly, a circuit board is provided with a plurality of bonding pads formed thereon for connecting to the die pads. Afterward, an isolation layer is formed on the circuit board to cover the bonding pads. The isolation layer is then etched to expose both an upper surface and a portion of the sidewall of the pads. Finally, a conductive plating layer is formed to cover the upper surface and the portion of the sidewall by electro-plating.

A fine-pitch packaging substrate solely for flip-chip packaging is also disclosed in the present invention. The fine-pitch packaging substrate comprises a circuit board, a plurality of packaging pads, and an isolation pattern. The bonding pads are formed on the circuit board. The isolation pattern is formed to fill the space between neighboring bonding pads and cover all the exposed surfaces of the circuit board. The isolation pattern has a bigger thickness with respect to the bonding pads and further has a plurality of openings to expose the whole upper surface of the bonding pads for locating the bumps.

Reference will now be made in detail to the preferred embodiments of the present invention, examples of which are illustrated in the accompanying drawings. Wherever possible, the same reference numbers will be used throughout the drawings to refer to the same or like parts.

### BRIEF DESCRIPTION OF THE DRAWINGS

The present invention will now be specified with reference to its preferred embodiment illustrated in the drawings, in which:

FIGS. 1A and 1B depict schematic top and cross-section views of a typical packaging substrate;

FIGS. 2A to 2E depict schematic views of a first preferred embodiment of a packaging method in accordance with the present invention;

FIGS. 3A to 3F depict schematic views of a second preferred embodiment of a packaging method in accordance with the present invention;

FIGS. 3G to 3H depict schematic views of a preferred embodiment of a flip-chip packaging method engaging the packaging substrate of FIG. 3E; and

FIGS. 4A to 4F depict schematic views of a third preferred embodiment of a packaging method in accordance with the present invention.

### DETAIL DESCRIPTION OF THE PREFERRED EMBODIMENTS

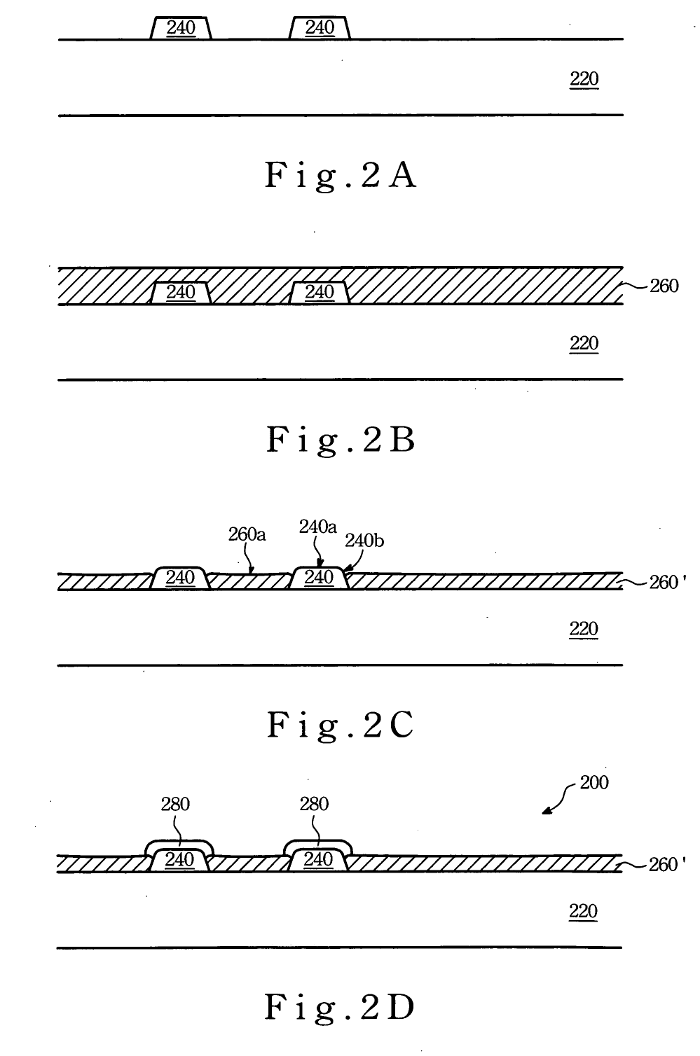

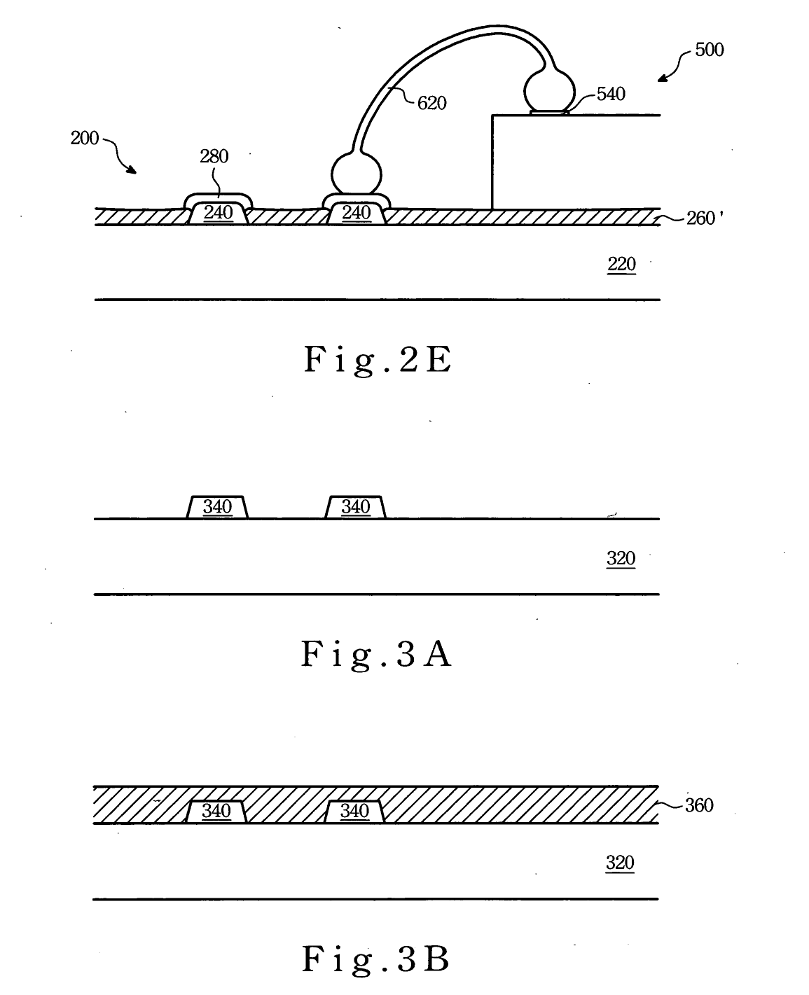

FIGS. 2A to 2E depict a first preferred embodiment of a packaging method in accordance with the present invention. Firstly, as shown in FIG. 2A, a plurality of bonding pads 240 is formed on an upper surface of a circuit board 220. Afterward, as shown in FIG. 2B, an isolation layer 260 is formed on the circuit board 220 to fill the space between neighboring bonding pads 240 and also cover all the bonding pads 240 and the exposed surfaces of the circuit board 220. Then, referring to FIG. 2C, the isolation layer 260 is partly removed by etching to expose an upper surface 240a and a portion of the sidewall 240b of the bonding pads 240 to conclude an isolation pattern 260′. As a preferred embodiment, the etching process of FIG. 2C may be applied by utilizing a chosen etching solution and a controlled etching duration to adjust the depth of etching to a preset level and have the upper surface 260a of isolation pattern 260 lie at the same level with or below the upper surface 240a of the bonding pads 240. The isolation layer 260 may be partly removed by e.g. etching or mechanical polishing.

Afterward, as shown in FIG. 2D, a conductive plating layer 280 is formed on the circuit board 220 and covers all the exposed surfaces of the bonding pads 240 by electro-plating to finish the formation of the packaging substrate 200. It is also noted that the conductive plating layer 280 definitely has some extended portion outward from the sidewall of the bonding pads 240 to expand the connectable area on the packaging substrate 200. Finally, as shown in FIG. 2E, a die 500 with die pads 540 positioned on an upper surface thereof is placed on the packaging substrate 200. A wire-bonding (W/B) process is then carried out to connect the die pads 540 on the die 500 and the conductive plating layer 280 by using conductive wires 620. It is noted that an additional solder mask layer (not shown in this figure) may be formed—over the isolation pattern 260′ if needed.

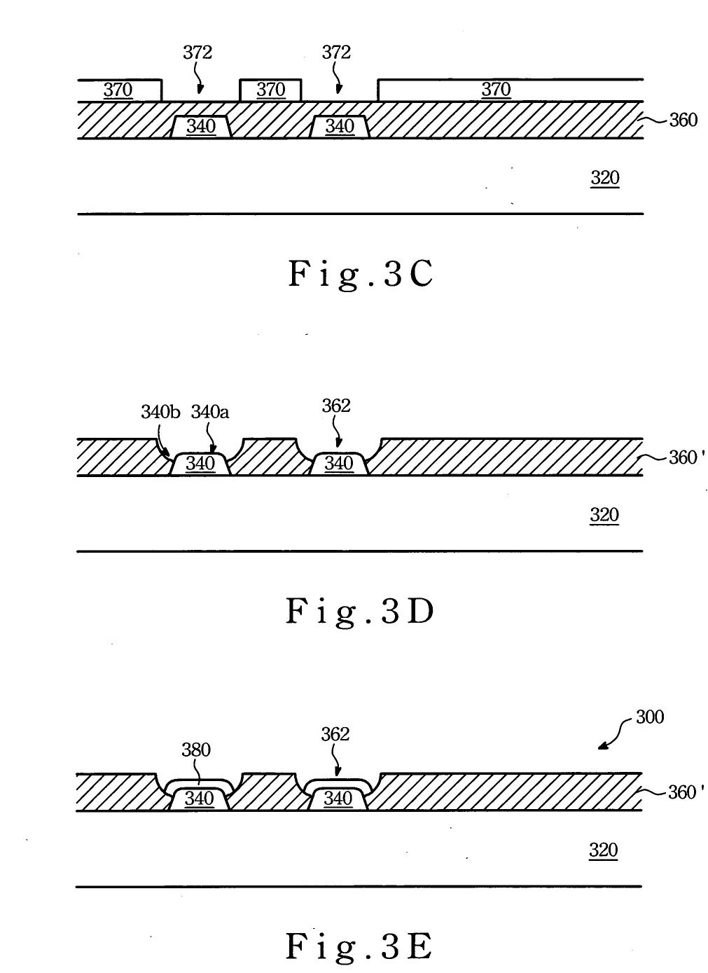

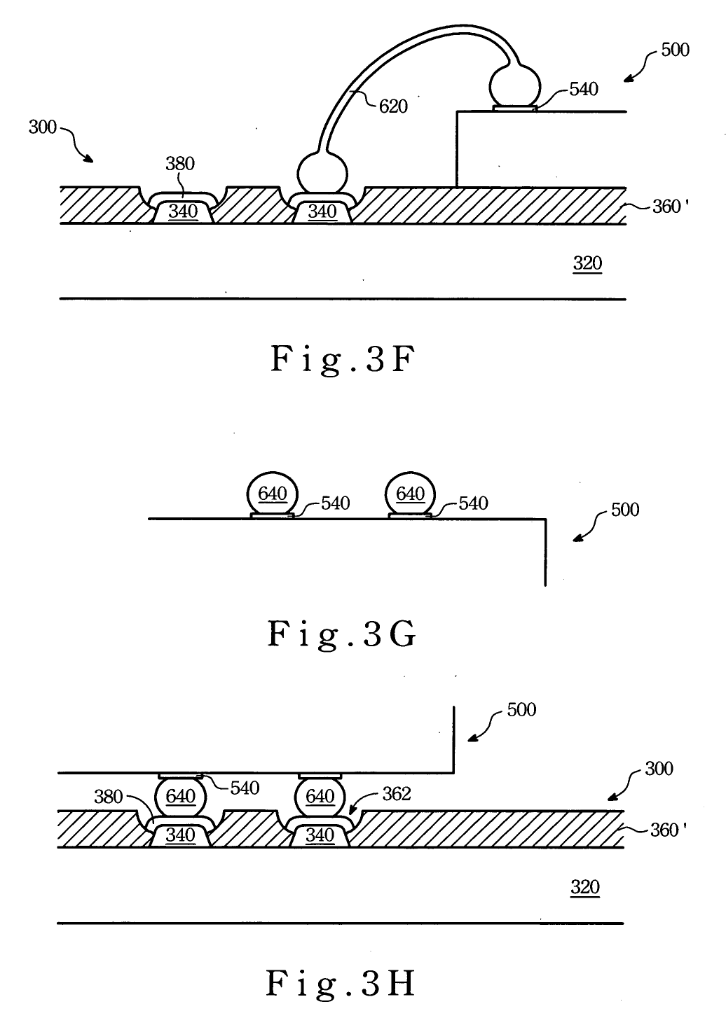

FIGS. 3A to 3F depict schematic views of a second preferred embodiment of a packaging method in accordance with the present invention. Firstly, as shown in FIG. 3A, a plurality of bonding pads 340 is formed on an upper surface of a circuit board 320. Afterward, as shown in FIG. 3B, an isolation layer 360 is formed on the circuit board 320 to fill the space between neighboring bonding pads 340 and cover all the bonding pads 340 and the exposed surfaces of the circuit board 320. Then, referring to FIG. 3C, a photoimageable resist pattern 370 is formed on the isolation layer 360 with some openings 372 right above the bonding pads 340 and the adjacent. Afterward, as shown in FIG. 3D, an etching process is carried out through the openings 372 of the photoimageable resist pattern 370 to form cavities 362, which are utilized to expose an upper surface 340a and a portion of the sidewall 340b of the bonding pads 340, and concludes an isolation pattern 360′. The laser ablation for forming cavities 362 may be in place of the etching process.

Afterward, as shown in FIG. 3E, a conductive plating layer 380 is formed in the cavities 362 to cover all the exposed surfaces of the bonding pads 340 by electro-plating to finish the formation of the packaging substrate 300. It is noted that the conductive plating layer 380 is provided with some portions extended outward from the sidewall of the bonding pads 340 so as to expand the connectable area on the packaging substrate 300. Finally, as shown in FIG. 3F a die 500 with die pads 540 positioned on an upper surface thereof is placed on the packaging substrate 300. A wire-bonding process is then carried out to connect the conductive plating layer 380 and the die pads 540 of the die 500 by using conductive wires 620. It is noted that an additional solder mask layer (not shown in this figure) may be formed-over the isolation pattern 360′ if needed.

In addition to the wire-bonded packaging, the packaging substrate of FIG. 3E is also applicable to a flip-chip packaging. Referring to FIG. 3G, for making a flip-chip packaging, a plurality of bumps 640 must be formed on the die pads 540 of the die 500. Then, as shown in FIG. 3H, the die 500 is flipped and placed on the packaging substrate 300. The bumps 640 on the die pads 540 are self-aligned in the cavities 362 of the isolation pattern 360′ to contact with the conductive plating layer 380 inside the cavities 362. Afterward, by a re-flowing process, the bumps 640 are adhered to the conductive plating layer 380 to hold the die 500 and the packaging substrate 300 together.

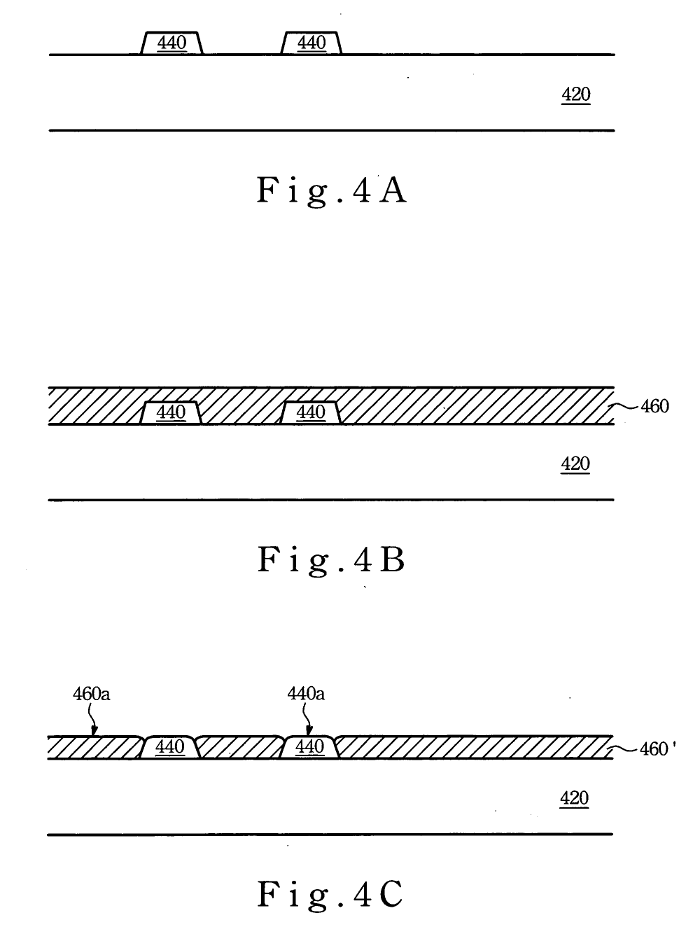

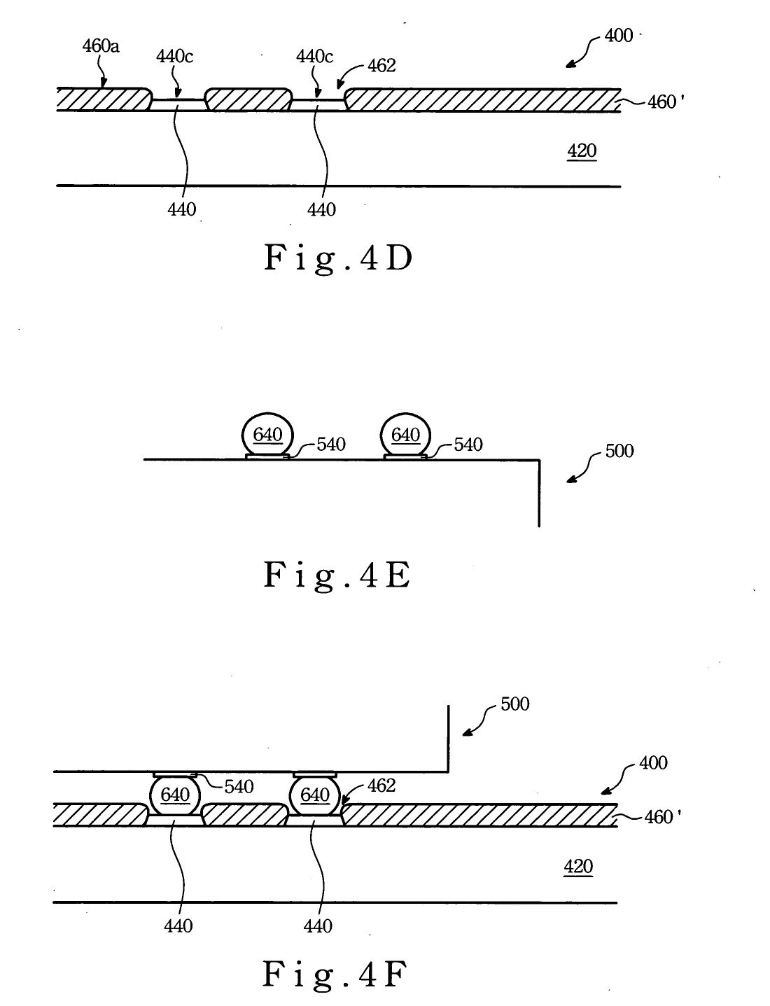

FIGS. 4A to 4F depict schematic views of a third preferred embodiment of a packaging method solely for flip-chip packaging in accordance with the present invention. Firstly, as shown in FIG. 4A, a plurality of bonding pads 440 is formed on an upper surface of a circuit board 420. Afterward, as shown in FIG. 4B, an isolation layer 460 is formed on the circuit board 420 to fill the space between neighboring bonding pads 440 and cover all the bonding pads 440 and all the exposed surfaces of the circuit board 420. Then, referring to FIG. 4C, a blank etching or polishing process is carried out by setting the upper surface 440a of the bonding pads 440 as a stop layer for exposing the upper surface 440a. Therefore, the resulted isolation pattern 460′ merely covers the whole sidewall of the bonding pads 440 and the upper surface 440a of the packaging pads 440 is totally exposed. Afterward, referring to FIG. 4D, another etching process is further carried out through the isolation pattern 460′ by etching the bonding pads 440 to minimize the thickness thereof. Therefore, the etched upper surface 440c of the bonding pads 440 lies below the upper surface 460a of the isolation pattern 460′, and a plurality of opening 462 are thus formed right above the bonding pads 440 to conclude the packaging substrate 400.

As shown in FIG. 4E, for making a flip-chip packaging, a plurality of bumps 640 must be formed on the die pads 540 of the die 500. Then, as shown in FIG. 4F, the die 500 is flipped and placed on the packaging substrate 400. The bumps 640 on the die pads 540 are aligned to the openings 462 of the isolation pattern 460′ right above the bonding pads 440 to contact to the bonding pads 440. Afterward, by a re-flowing process, the bumps 640 are adhered to the bonding pads 440 to hold the die 500 and the packaging substrate 400 together.

By contrast to the prior art packaging substrate, the packaging substrates provided in the present invention and the disclosed packaging methods have the following advantages:

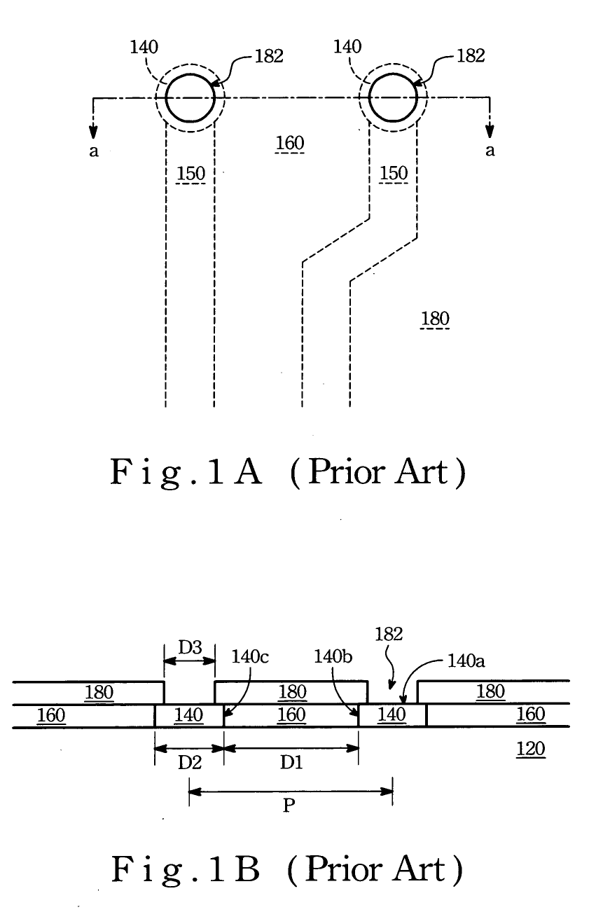

1. As shown in FIG. 1B, the pitch length P of the neighboring bonding pads 140 on the packaging substrate equals to a sum of the distance D1 between the opposing sidewalls 140b and 140c and the width D2 of the bonding pad 140. Whereas, in the packaging substrate in accordance with the present invention as shown in FIGS. 2D and 3E, the conductive plating layer 280,380 is formed to expand the connectable area on the packaging substrate 200,300. Therefore, a smaller bonding pad may be used to achieve an identical connectable area. Moreover, the smaller bonding pad may further result a fine-pitch packaging, and a high-density pad array is thus available.

2. In a flip-chip packaging, the cavities 362 of FIG. 3E or the openings 462 of FIG. 4D are used for locating the bumps 640 adhered on the die 500. The bumps 640 are self-aligned to fit into the cavities 362 or the openings 462. In addition, the isolation patterns 360′ and 460′ of FIGS. 3E and 4F can be used to isolate the neighboring bumps and functionally replace the solder mask 180 of FIG. 1B to simplify the fabrication process of the packaging substrate.

With the example and explanations above, the features and spirits of the invention will be hopefully well described. Those skilled in the art will readily observe that numerous modifications and alterations of the device may be made when retaining the teaching of the invention. Accordingly, the appended claims are intended to cover all embodiments without departing from the spirit and scope of the present invention.

1. A fine-pitch packaging substrate comprising:
a circuit board;
a plurality of bonding pads formed on the circuit board;
an isolation pattern formed on the circuit board to fill the space between the neighboring packaging pads and cover all the exposed surfaces of the circuit board, wherein a portion of the isolation pattern adjacent to the packaging pads has a same or smaller thickness with respect to the packaging pads so as to expose an upper surface and a portion of the sidewall of the packaging pads; and
a conductive plating layer covering the upper surface and the portion of the sidewall of the packaging pads and extending outward from the sidewall to expand the connectable area on the fine-pitch packaging substrate.

2. The fine-pitch packaging substrate of claim 1, wherein a whole upper surface of the isolation pattern is located at the same level with or below the upper surface of the packaging pads.

3. The fine-pitch packaging substrate of claim 1, wherein the isolation pattern has a plurality of cavities aligning to the packaging pads to expose the upper surface and the portion of the sidewall of the packaging pads.

4. A fine-pitch packaging comprising:
a circuit board;
a plurality of bonding pads formed on an upper surface of the circuit board;
an isolation pattern formed on the circuit board to fill the space between the neighboring packaging pads and cover all the exposed surfaces of the circuit board, wherein a portion of the isolation pattern adjacent to the packaging pads has a same or smaller thickness with respect to the packaging pads to expose an upper surface and a portion of the sidewall of the packaging pads;
a conductive plating layer covering the upper surface and the portion of the sidewall of the packaging pads and extending outward form the sidewall to expand the connectable area on the fine-pitch packaging substrate;
at least one die with a plurality of die pads thereon assembled on the circuit board; and
an electric connecting means formed to electrically connect the die pads and the conductive plating layer.

5. The fine-pitch packaging of claim 4, wherein a whole upper surface of the isolation pattern is located at the same level with or below the upper surface of the packaging pads.

6. The fine-pitch packaging of claim 4, wherein the isolation pattern has a plurality of cavities aligning to the bonding pads to expose the upper surface and the portion of the sidewall of the bonding pads.

7. The fine-pitch packaging of claim 4, wherein the electric connecting means is a conductive wire formed in a wire-bonding process.

8. The fine-pitch packaging of claim 4 wherein the electric connecting means is a bump.

9. A fabrication method for forming a fine-pitch packaging substrate comprising the steps of:
providing a circuit board;
forming a plurality of bonding pads on the circuit board;
forming an isolation layer on the circuit board to cover all the bonding pads;
etching the isolation layer to expose an upper surface and a portion of the sidewall of the bonding pads; and
forming a conductive plating layer to cover the upper surface and the portion of the sidewall of the bonding pads.

10. The fabrication method of claim 9, wherein the etching step is carried out by blank etching the isolation layer to a level at the same level with or lower than the upper surface of the packaging pads so as to expose the upper surface and the portion of the sidewall of the packaging pads.

11. The fabrication method of claim 9, wherein the etching step is carried out with a photoimageable resist pattern to form a plurality of cavities aligning to the bonding pads and the adjacent in the isolation layer to expose the upper surface and the portion of the sidewall of the bonding pads.

12. A fine-pitch packaging substrate for a flip-chip packaging comprising:
a circuit board;
a plurality of bonding pads formed on the circuit board; and
an isolation pattern, which is formed on the circuit board to fill the space between the neighboring bonding pads and cover all the exposed surfaces of the circuit board, having a bigger thickness with respect to the packaging pads and having a plurality of openings to expose a whole upper surface of the packaging pads for locating bumps.

13. A fine-pitch flip-chip packaging comprising:
a circuit board;
a plurality of bonding pads formed on the circuit board;
an isolation pattern, which is formed on the circuit board to fill the space between the neighboring packaging pads and cover all the exposed surfaces of the circuit board, having a bigger thickness with respect to the bonding pads and having a plurality of openings to expose a whole upper surface of the bonding pads;
at least one die flipped and placed on the circuit board having a plurality of die pads aligning the bonding pads in the openings; and
a plurality of conductive bumps interposed between the die pads and the bonding pads to form electric connections between the die and the circuit board respectively.

14. A fabrication method of forming a fine-pitch packaging substrate comprising the steps of:
providing a circuit board;
forming a plurality of bonding pads on the circuit board;
forming an isolation layer on the circuit board to cover all the packaging pads;
blank etching the isolation layer by setting an upper surface of the bonding pads as an etching stop; and
selectively etching the packaging pads to minimize a thickness thereof to have the upper surface of the packaging pads lie below an upper surface of the isolation layer.
